(19) United States
(12) Patent Application Publication
(10) Pub. No.: US 2023/0037861 A1
(43) Pub. Date: Feb. 9, 2023

(54) SEMICONDUCTOR DEVICE AND METHOD OF MANUFACTURING THE SAME

(71) Applicant: Kioxia Corporation, Tokyo (JP)

(72) Inventor: Masato SHINI, Mie Mie (JP)

(73) Assignee: Kioxia Corporation, Tokyo (JP)

(21) Appl. No.: 17/674,101

(22) Filed: Feb. 17, 2022

(30) Foreign Application Priority Data
Aug. 5, 2021 (JP) 2021-129326

(51) Int. Cl. H01L 27/1156; H01L 27/11524

(52) U.S. Cl. CPC H01L 27/1156; H01L 27/11524

(57) ABSTRACT

A semiconductor device includes a first transistor and a second transistor. The first transistor includes first and second diffusion regions in a substrate, a first gate insulating film over the substrate, a first gate electrode over the first gate insulating film; first and second silicide layers on the first and second diffusion regions, respectively; and a first gate silicide layer on the first gate electrode. The second transistor includes third and fourth diffusion regions in the substrate; a second gate insulating film over the substrate; a second gate electrode over the second gate insulating film; and a second gate silicide layer on the second gate electrode. The second gate insulating film is thicker than the first gate insulating film, and at least a part of the third diffusion region and at least a part of the fourth diffusion region are covered by the second gate insulating film.

### CROSS-REFERENCE TO RELATED APPLICATIONS

This application is based upon and claims the benefit of priority from Japanese Patent Application No. 2021-129326, filed Aug. 5, 2021, the entire contents of which are incorporated herein by reference.

### BACKGROUND

### Technical Field

Embodiments described herein relate generally to a semiconductor device and a method of manufacturing the same.

### Related Art

In some cases, NAND flash memories may have three-dimensional stacks of memory cells.

### BRIEF DESCRIPTION OF THE DRAWINGS

FIG. 1 is a cross-sectional view showing a semiconductor device according to an embodiment.

FIG. 2 is a cross-sectional view for describing a method of manufacturing a semiconductor device according to the embodiment.

FIG. 3 is a cross-sectional view for describing the method of manufacturing a semiconductor device according to the embodiment.

FIG. 4 is a cross-sectional view for describing the method of manufacturing a semiconductor device according to the embodiment.

FIG. 5 is a cross-sectional view for describing the method of manufacturing a semiconductor device according to the embodiment.

FIG. 6 is a cross-sectional view showing a semiconductor device according to a comparative example.

FIG. 7 is a cross-sectional view for describing a method of manufacturing a semiconductor device according to a comparative example.

FIG. 8 is a cross-sectional view for describing the method of manufacturing a semiconductor device according to the comparative example.

### DETAILED DESCRIPTION

In some embodiments, a semiconductor device includes a first transistor and a second transistor. The first transistor includes first and second diffusion regions in a substrate, a first gate insulating film over the substrate, a first gate electrode over the first gate insulating film; first and second silicide layers on the first and second diffusion regions, respectively; and a first gate silicide layer on the first gate electrode. The second transistor includes third and fourth diffusion regions in the substrate; a second gate insulating film over the substrate; a second gate electrode over the second gate insulating film; and a second gate silicide layer on the second gate electrode. The second gate insulating film is thicker than the first gate insulating film, and at least a part of the third diffusion region and at least a part of the fourth diffusion region are covered by the second gate insulating film.

Some embodiments will be described hereinafter with reference to the drawings.

In the following description, components having the same or similar functions are designated by the same reference signs. Overlapping description of these components may be omitted. In the application, term “connection” may include not only direct or indirect physical connection with or without direct or indirect electrical connection, but also direct or indirect electrical connection with or without direct or indirect physical connection. In this application, the phrase “disposed on a substrate”, or “disposed on substrate section” may not only include all or entire parts of a structural element are positioned on the substrate, but also include part of the structural element is positioned on the substrate on substrate section. In the application, the terms “on”, “over”, or “above” should not be defined based on the direction of gravity, but may refer to a relative direction with reference to other element in a final product. In the application, the term “over”, or “above” may not only include a case where an element is in contact directly with the other element but also another case where the element is spatially separate from the other element. In the application, the terms “parallel to,” “perpendicular to” or “the same” may include “substantially parallel to,” “substantially perpendicular to” or “substantially the same,” respectively.

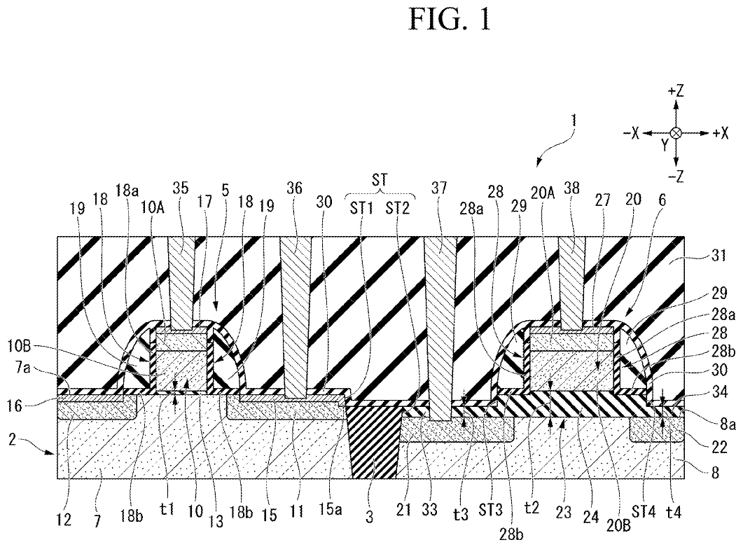

First, a +X direction, a −X direction, a +Y direction, a −Y direction, a +Z direction, and a −Z direction will be defined. The +X direction, the −X direction and the +Y direction, and the −Y direction are directions parallel to a top surface 7a (or a top surface 8a) of a first substrate section 7, which will be described below, (or a second substrate section 8) (see FIG. 1). The +X direction is a direction from the first substrate section 7 to the second substrate section 8, which will be described below. The −X direction is a direction opposite to the +X direction. When the +X direction and the −X direction are not discriminated, they are simply referred to as “an X direction.” The +Y direction, and the −Y direction are directions crossing (for example, substantially perpendicular to) the X direction. The +Z direction and the −Z direction are directions crossing (for example, substantially perpendicular to) the X direction and the Y direction, and a thickness direction of a semiconductor substrate 2, which will be described below. The direction is a direction from the side of a bottom portion toward an upper portion of the first substrate section 7 (or the second substrate section 8) in the thickness direction. The −Z direction is a direction opposite to the +Z direction. When the +Z direction and the −Z direction are not discriminated, they are simply referred to as “a Z direction.” In the specification, “the +Z direction” may be referred to as “upward” and “the −Z direction” may be referred to as “downward.” However, these expressions are for convenience only and do not specify the direction of gravity.

### Embodiments

A semiconductor device 1 will be described. FIG. 1 is a cross-sectional view showing the semiconductor device 1. The semiconductor device 1 is integrated into a semiconductor storage device such as a NAND flash memory or the like, and used to control a memory cell array including a plurality of memory cells.

The semiconductor substrate 2 is a silicon substrate including single crystal silicon. One or more device-isolating insulation regions 3 (hereinafter referred to as “isolations 3”) formed of an insulating material such as silicon oxide are disposed on a part of an upper layer portion of the semiconductor substrate 2. The isolations 3 are disposed between a first transistor 5 and a second transistor 6, which will be described below, in the X direction. The semiconductor substrate 2 has the first substrate section 7 and the second substrate section 8 separated in the X direction via the isolations 3. A thickness of the first substrate section 7 is greater than that of the second substrate section 8.

A step difference ST is disposed between the first substrate section 7 and the second substrate section 8 based on a difference in the thickness in the Z direction. The top surface (upper surface) 8a of the second substrate section 8 is disposed below the top surface (upper surface) 7a of the first substrate section 7. Accordingly, for example, a difference in thickness between a first gate insulating film 13 of the first transistor 5 and a second gate insulating film 23 of the second transistor 6, which will be described below, is absorbed (see FIG. 1). However, the reason why the step difference ST is disposed is not limited to the above-mentioned example.

The first transistor 5 is disposed on the first substrate section 7. The second transistor 6 is disposed on the second substrate section 8. Each of the first transistor 5 and the second transistor 6 is an electric field effect transistor. The first transistor 5 is disposed on one side of the isolations 3 (for example, the side in the −X direction) in the X direction. The second transistor 6 is disposed on the other side of the isolations 3 (for example, the side in the +X direction) in the X direction.

<First Transistor>

The first transistor 5 has, for example, a first gate electrode 10, a first source region 11, a first drain region 12, the first gate insulating film 13, a first-diffusion-layer-side silicide layer 15, a second-diffusion-layer-side silicide layer 16, a first gate silicide layer 17, an insulating film 18, and an insulating sidewall 19. The first source region 11 is an example of “a first diffusion region.” The first drain region 12 is an example of “a second diffusion region.” However, the first drain region 12 may correspond to an example of “the first diffusion region.” The first source region 11 may correspond to an example of “the second diffusion region.”

The first gate electrode 10 is disposed on the first gate insulating film 13, which will be described below, on the side opposite to the semiconductor substrate 2. The first gate electrode 10 is disposed above the top surface 7a of the first substrate section 7. The first gate electrode 10 is disposed between the first source region 11 and the first drain region 12 in the X direction. The first gate electrode 10 includes, for example, a layered structure of a first semiconductor layer 10A formed of polysilicon or the like and a second semiconductor layer 10B formed of polysilicon or the like. For example, the second semiconductor layer 10B is disposed on the first gate insulating film 13. The first semiconductor layer 10A is disposed on the second semiconductor layer 10B. Further, the first gate electrode 10 may be formed of only one of the first semiconductor layer 10A and the second semiconductor layer 10B. In the example of FIG. 1, a thickness of the first semiconductor layer 10A in the Z direction is greater than that of the second semiconductor layer 10B in the Z direction. Further, the first gate electrode 10 may have a configuration in which another layer is interposed between the first semiconductor layer 10A and the second semiconductor layer 10B or a partial metal layer may be interposed therebetween.

The first source region 11 and the first drain region 12 are formed at a predetermined depth as a part of the top surface portion of the first substrate section 7. For example, the first source region 11 and the first drain region 12 are formed by doping impurities in an upper portion of the first substrate section 7. The first source region 11 and the first drain region 12 are separated from each other in the X direction. The first gate insulating film 13 is disposed on the top surface of the first substrate section 7 between the first source region 11 and the first drain region 12 separated from each other in the X direction.

In the embodiment, each of the first source region 11 and the first drain region 12 includes an n⁺-semiconductor or a p-semiconductor (for example, a p⁺-semiconductor). In the application, “the n⁺-semiconductor” is, for example, an n-semiconductor with an impurity concentration of 10¹⁵ atoms; cm² or more.

The first gate insulating film 13 is formed on the top surface 7a of the first substrate section 7. At least a part of the first gate insulating film 13 is located between the first gate electrode 10 and the top surface 7a of the first substrate section 7. The first gate insulating film 13 is formed of, for example, a silicon oxide film. In the embodiment, a thickness t1 of the first gate insulating film 13 in the Z direction is smaller than a thickness t2 of the second gate insulating film 23 in the Z direction, which will be described below. A maximum voltage of current flowing through the first transistor 5 is smaller than a maximum voltage of current flowing through the second transistor 6.

The first-diffusion-layer-side silicide layer 15 is formed to be thinner than the first source region 11 on the side of the top surface of the first source region 11. The first-diffusion-layer-side silicide layer 15 includes, for example, a nickel platinum silicide layer (NiPtSi layer). The first-diffusion-layer-side silicide layer 15 is formed by, for example, supplying metallic elements such as nickel (Ni) or platinum (Pt) to the first source region 11 and thermally diffusing these metallic elements.

The second-diffusion-layer-side silicide 16 is formed to be thinner than a second source region 12 on the side of a top surface of the second source region 12. The second-diffusion-layer-side silicide layer 16 includes, for example, a nickel platinum silicide layer (NiPtSi layer). The second-diffusion-layer-side silicide layer 16 is formed by, for example, supplying metallic elements such as nickel (Ni) or platinum (Pt) to the second source region 12 and thermally diffusing these metallic elements.

The first-diffusion-layer-side silicide layer 15 and the second-diffusion-layer-side silicide 16 are separated from each other in the X direction. The first gate insulating film 13 is disposed on the top surface of the first substrate section 7 between the first-diffusion-layer-side silicide layer 15 and the second-diffusion-layer-side silicide 16 separated from each other in the X direction.

The first gate silicide layer 17 is formed on an upper portion of the first semiconductor layer 10A. In a cross section of FIG. 1, the first gate silicide layer 17 has the same width as the first semiconductor layer 10A. However, the first gate silicide layer 17 and the first semiconductor layer 10A may have the same width or may have different widths. The first gate silicide layer 17 completely covers the upper surface of the first semiconductor layer 10A. When the first semiconductor layer 10A is formed of polysilicon, the layer is formed by supplying metallic elements such as nickel (Ni), platinum (Pt), or the like, and then sally diffusing these metallic elements on the upper portion of the polysilicon layer after formation of the polysilicon layer. The first gate silicide layer 17 is formed on the first semiconductor layer 10A on the side opposite to the substrate 2. In the example of FIG. 1, the first gate silicide layer 17 is formed to be thinner than the first semiconductor layer 10A. Further, while the thickness of the first gate silicide layer 17 is equal to the thickness of the first semiconductor layer 10A, alternatively, the first gate silicide layer 17 may be formed to be thicker than the first semiconductor layer 10A.

The insulating film 18 has a side surface portion 18a that covers a side portion of the first gate insulating film 13, a side portion of the second semiconductor layer 10B and a side portion to a central portion of the first semiconductor layer 10A in the thickness direction (the Z direction). The insulating film 18 has a bottom portion 18b that covers a part of the top surface 7a of the first substrate section 7 on the side of the first gate insulating film 13. The insulating film 18 is formed in an L shape in a cross section of FIG. 1. Further, in the insulating film 18, the height of the side surface portion 18a in the Z direction is not particularly limited. The insulating film 18 can be formed at a height where a part or the entirety of the side surface of the second semiconductor layer 10B is covered or a height where a part or the entirety of the side surface of the first semiconductor layer 10A is covered in addition to the second semiconductor layer 10B.

In the bottom portion 18b of the insulating film 18 disposed on the side of the first gate insulating film 13 in the +X direction, the portion that covers the top surface 7a of the first substrate section 7 is formed to a position at which a part of the first source region 11 adjacent thereto is covered. In the bottom portion 18b of the insulating film 18 disposed on the side of the first gate insulating film 13 in the −X direction, the portion that covers the top surface 7a of the first substrate section 7 is formed to a position where a part of the first drain region 12 adjacent thereto is covered. The insulating film 18 is formed of, for example, a silicon oxide film, a silicon nitride film, or the like.

The insulating sidewall 19 is formed of, for example, a silicon nitride film or a silicon oxide film. The insulating sidewall 19 is adhered to the insulating film 18 on an outer side of the insulating film 18 when seen from a center of the first transistor 5 (a center of the first gate electrode 10), and covers the side portion of the second semiconductor layer 10B, the side portion of the first semiconductor layer 10A, and the side portion of the first gate silicide layer 17. The bottom portion of the insulating sidewall 19 covers the side of the bottom portion of the insulating film 18. Further, a height of the insulating sidewall 19 in the Z direction is not particularly limited. The insulating sidewall 19 may be formed at a height where a part or the entirety of the side surface of the second semiconductor layer 10B is covered or at a height where a part or the entirety of the side surface of the first semiconductor layer 10A is covered in addition to the side surface of the second semiconductor layer 10B.

<Second Transistor>

The second transistor 6 has, for example, a second gate electrode 20, a second source region 21, a second drain region 22, the second gate insulating film 23, a second gate silicide layer 27, an insulating film 28, and an insulating sidewall 29. The second source region 21 is an example of “a third diffusion region.” The second drain region 22 is an example of “a fourth diffusion region.” However, the second drain region 22 may correspond to an example of “the third diffusion region,” and the second source region 21 may correspond to an example of “the fourth diffusion region.”

The second gate electrode 20 is disposed on the second gate insulating film 23, which will be described below, on the side opposite to the semiconductor substrate 2. The second gate electrode 20 is located above the top surface 8a of the second substrate section 8. The second gate electrode 20 is located between the second source region 21 and the second drain region 22 in the X direction. The second gate electrode 20 is constituted by, for example, a first semiconductor layer 20A formed of polysilicon or the like, and a second semiconductor layer 20B formed of polysilicon or the like. For example, the second semiconductor layer 20B is disposed on the second gate insulating film 23. The first semiconductor layer 20A is disposed on the semiconductor layer 20B. Further, the second gate electrode 20 may be constituted by only one of the first semiconductor layer 20A and the second semiconductor layer 20B. In the example of FIG. 1, a thickness of the second semiconductor layer 20B in the Z direction is greater than that of the first semiconductor layer 20A in the Z direction. Further, the second gate electrode 20 may have a configuration in which another layer is interposed between the first semiconductor layer 20A and the second semiconductor layer 20B or a partial metal layer is interposed therebetween.

The second source region 21 and the second drain region 22 are formed as a part of the upper portion of the second substrate section 8. For example, the second source region 21 and the second drain region 22 are formed by doping impurities on the upper portion of the second substrate section 8. The second source region 21 and the second drain region 22 are separated from each other in the X direction.

In the embodiment, each of the second source region 21 and the second drain region 22 includes an n⁻-semiconductor. In the specification, “n⁻-semiconductor” means an n-semiconductor with, for example, an impurity concentration smaller than 10¹⁵ atoms/cm². An example of the impurity concentration of the second source region 21 and the second drain region 22 is 10¹² atoms/cm². However, the conductivity type of the second source region 21 and the second drain region 22 is not limited to the above-mentioned example and may be the same as that of the first source region 11 and the first drain region 12.

The second gate insulating film 23 is formed on the top surface 8a of the second substrate section 8. At least a part of the second gate insulating film 23 is located between the second gate electrode 20 and the top surface 8a of the second substrate section 8. The second gate insulating film 23 is formed of, for example, a silicon oxide film. In the embodiment, the thickness t2 of the second gate insulating film 23 in the Z direction is greater than the thickness t1 of the first gate insulating film 13 in the Z direction. A maximum voltage of current flowing through the second transistor 6 is greater than that of current flowing through the first transistor 5.

In the embodiment, the second gate insulating film 23 has a first portion 24 disposed at a central side in the X direction, and a second portion 33 and a third portion 34 disposed at both sides in the X direction. In the embodiment, the first portion 24, the second portion 33, and the third portion 34 are formed integrally with each other and connected to each other.

The first portion 24 is located between the semiconductor substrate 2 and the second gate electrode 20. In the embodiment. an end portion of the first portion 24 on the side in the −X direction is located on the second source region 21. An end portion of the first portion 24 on the side in the +X direction is located on the second drain region 22. The thickness t2 of the first portion 24 in the Z direction is greater than the thickness t1 of the first gate insulating film 13 in the Z direction.

The second portion 33 is located on the side of the first portion 24 in the −X direction, and disposed on the second source region 21. The second portion 33 covers at least a part of the second source region 21 from a side opposite to the semiconductor substrate 2. In the embodiment, the entire second source region 21 shown in FIG. 1 is covered with the first portion 24 and the second portion 33 from a side opposite to the semiconductor substrate 2. A thickness t3 of the second portion 33 in the Z direction is smaller than the thickness t2 of the first portion 24 in the Z direction. Accordingly, the step difference ST3 is disposed between the first portion 24 and the second portion 33. In addition, the thickness t3 of the second portion 33 in the Z direction is greater than the thickness t1 of the first gate insulating film 13 in the Z direction.

The third portion 34 is located on the side of the first portion 24 in the +X direction and disposed on the second drain region 22. The third portion 34 covers at least a part of the second drain region 22 from a side opposite to the semiconductor substrate 2. In the embodiment, the entire second drain region 22 shown in FIG. 1 is covered with the first portion 24 and the third portion 34 from a side opposite to the semiconductor substrate 2. A thickness t4 of the third portion 34 in the Z direction is smaller than the thickness t2 of the first portion 24 in the Z direction. Accordingly, the step difference ST4 is disposed between the first portion 24 and the third portion 34. In addition, the thickness t4 of the third portion 34 in the Z direction is greater than the thickness t1 of the first gate insulating film 13 in the Z direction.

Further, while the thicknesses of the first portion 24 and the third portion 34 are different and the step difference is disposed between them in the configuration of FIG. 1, the step difference may not be disposed. The first portion 24 and the third portion 34 may be formed in a state in which the thicknesses of the first portion 24 and the third portion 34 are equal and there is no step difference.

In the embodiment, an end portion of the first source region 11 on the side in the +X direction reaches a side surface of one of the isolations 3. Similarly, an end portion of the first-diffusion-layer-side silicide layer 15 on the side in the +X direction reaches an upper end of a side surface of one of the isolations 3, and comes into contact with the isolation 3 from a side. Meanwhile, an end portion of the second source region 21 on the side in the −X direction reaches a side surface of the other of the isolations 3 and comes in contact with the isolation 3 from a side. Similarly, an end portion of the second gate insulating film 23 on the side of the second portion 33 in the −X direction reaches the side surface of the isolation 3 and comes in contact with the isolation 3 from a side.

A position of the top surface (upper surface) 7a of the first substrate section 7 in the Z direction is the same as that of the upper surface of the first-diffusion-layer-side silicide layer 15 in the Z direction. The first step difference ST1 is formed between these upper surfaces and the upper surfaces of the isolations 3. The second step difference ST2 is formed between the upper surfaces of the isolations 3 and the upper surface 8a of the second substrate section 8 (the upper surface of the second source region 21). The upper surface of the isolation 3 is located below the top surface (upper surface) 7a of the first substrate section 7. The upper surface of the isolation 3 is located above the upper surface of the second source region 21.

An extension portion 15a having a thickness in the Z direction that is greater than that of the other portion of the first-diffusion-layer-side silicide layer 15 is formed on an end portion of the first-diffusion-layer-side silicide layer 15 on the side in the +X direction. For example, the shallowest portion of the extension portion 15a reaches near the upper surface of the isolation 3.

The second portion 33 of the second gate oxide film 23 is disposed on the isolation 3 on the side of the upper surface of the third diffusion region 21 from the second step difference ST2. The second portion 33 is formed by extending a part of the second gate insulating film 23 to the isolation 3. The thickness t3 of the second portion 33 in the Z direction is formed to a thickness that can remove the second step difference ST2 between the upper surface of the second source region 21 and the upper surface of the isolation 3 (for example, the same thickness as the second step difference ST2). In the example shown in FIG. 1, the upper surface of the isolation 3 is flush with the upper surface of the second portion 33.

The second gate silicide layer 27 is formed on the second gate electrode 20. In the cross section of FIG. 1, the second gate silicide layer 27 has the same width as that of the second gate electrode 20. However, the second gate silicide layer 27 and the first semiconductor layer 20A may have the same width or may have different widths. The second gate silicide layer 27 completely covers the upper surface of the second gate electrode 20. When the second gate electrode 20 is formed of a polysilicon layer, after formation of the polysilicon layer, metallic elements such as nickel (Ni), platinum (Pt), or the like, are supplied, and then, these metallic elements are thermally diffused to form the second gate silicide layer 27. The second gate silicide layer 27 is formed at a side of the second gate electrode 20 opposite to the substrate 2. In the example of FIG. 1, the second gate silicide layer 27 is formed to be thinner than the first semiconductor layer 20A. The second gate silicide layer 27 is formed of the same material and has the same thickness as those of the first gate silicide layer 17. Further, while the thickness of the second gate silicide layer 27 is equal to the thickness of the first semiconductor layer 20A, alternatively, the second gate silicide layer 27 may be formed to be thicker than the first semiconductor layer 20A.

The insulating film 28 has a side surface portion 28a that covers a side portion of the second semiconductor layer 20B and a side portion to a central portion of the first semiconductor layer 20A in the thickness direction (Z direction), and a bottom portion 28b that covers a part of the second gate insulating film 23 on the side of the second gate insulating film 23. In the insulating film 28 disposed on the side of the second gate electrode 20 in the +X direction, the bottom portion 28b that covers a part of the second gate insulating film 23 is formed to a position where a part of the second drain region 22 is covered. In the insulating film 28 disposed on the side of the second gate electrode 20 in the -X direction, the bottom portion 28b that covers a part of the second gate insulating film 23 is formed to a position that covers a part of the second source region 21. The insulating film 28 is constituted by, for example, a silicon oxide film or a silicon nitride film.

The insulating sidewall 29 is formed of, for example, a silicon nitride film. The insulating sidewall 29 is adhered to the insulating film 28 to cover the side portions of the second semiconductor layer 20B, the first semiconductor layer 20A and the second gate silicide layer 27 at an outer side of the insulating film 28 when seen from a center of the second transistor 6. The bottom portion of the insulating sidewall 29 is formed to come into contact with the bottom portion 28b of the insulating film 28.

As shown in FIG. 1, the semiconductor device 1 has a protective film 30 and an insulating layer 31.

The protective film 30 covers the first transistor 5, the isolations 3, the second transistor 6 and the semiconductor substrate 2 around them. In the embodiment, the protective film 30 covers the first transistor 5 and the second transistor 6, and comes into contact with the first-diffusion-layer-side silicide layer 15, the first gate silicide layer 17, the second-diffusion-layer-side silicide layer 16, the second portion 33 of the gate insulating film 23, the second gate silicide layer 27, and the third portion 34 of the gate insulating film 23. Specifically describing, the protective film 30 covers, for example, the top surface of the first drain region 12, the top surface of the insulating sidewall 19, the top surface of the first gate silicide layer 17, and the top surface of the first-diffusion-layer-side silicide layer 15. In addition, the protective film 30 covers the upper surface of the isolation 3. Further, the protective film 30 covers the top surface of the second portion 33 of the gate insulating film 23, the top surface of the insulating sidewall 29, the top surface of the second gate silicide layer 27, and the top surface of the third portion 34 of the gate insulating film 23.

The insulating layer 31 is formed of a silicon oxide film or the like. The insulating layer 31 covers the protective film 30 and is formed on the protective film 30. The insulating layer 31 is formed to be thicker than the protective film 30, and covers the first transistor 5 and the second transistor 6. The insulating layer 31 has a sufficient thickness for the purpose of burying the step difference formed between the top surface of the first substrate section 7, the top surface of the second substrate section 8, the first transistor 5 and the second transistor 6.

<Contact Electrode>

Next, a contact electrode will be described.

As shown in FIG. I, a first contact electrode 35 passing through the insulating-layer 31 and the protective film 30 in the Z direction and reaching the first gate silicide layer 17 is formed above the first gate electrode 10. A second contact electrode 36 passing through the insulating layer 31 and the protective film 30 in the Z direction and reaching the first-diffusion-layer-side silicide layer 15 is formed above the first-diffusion-layer-side silicide layer 15.

A lower end of the first contact electrode 35 reaches a middle portion of the first gate silicide layer 17 in the thickness direction (Z direction) without passing through the first gate silicide layer 17.

A lower end of the second contact electrode 36 reaches a middle portion of the first-diffusion-layer-side silicide layer 15 in the thickness direction (Z direction) without passing through the first-diffusion-layer-side silicide layer 15.

A third contact electrode 37 passing through the insulating layer 31, the protective film 30 and the second portion 33 of the gate insulating film 23 in the Z direction and reaching the second source region 21 is formed above the second source region 21.

A lower end of the third contact electrode 37 reaches a middle portion of the second source region 21 in the thickness direction (Z direction) without passing through the second source region 21.

A fourth contact electrode 38 passing through the insulating layer 31 and the protective film 30 in the Z direction and reaching the second gate silicide layer 27 is formed above the second gate electrode 20.

A lower end of the fourth contact electrode 38 reaches a middle portion of the second gate silicide layer 27 in the thickness direction (Z direction) without passing through the second gate silicide layer 27.

Further, a structure of the contact electrodes 35, 36, 37 and 38 shown in FIG. 1 is an example, and of course, a structure of each contact electrode is not limited to the example of FIG. 1.

<Method of Manufacturing Semiconductor Device>

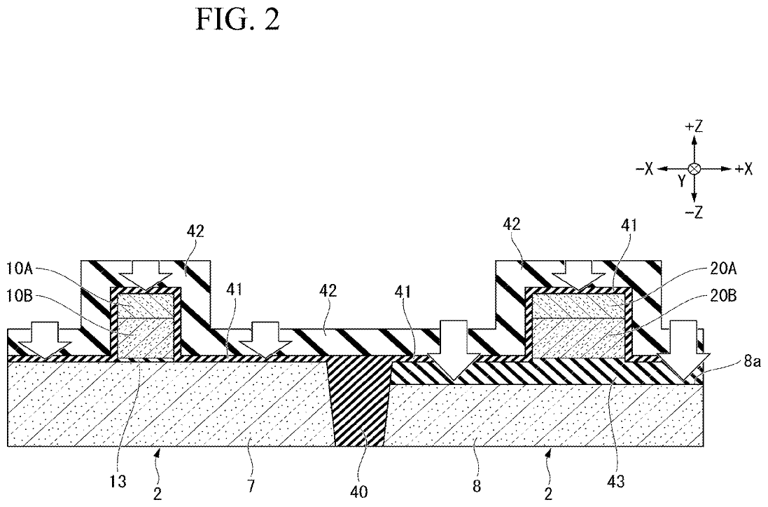

Hereinafter, an example of a method of manufacturing a semiconductor device 1 will be described with reference to FIG. 2 to FIG. 5.

In FIG. 2, an insulating portion 40 that is a base of the isolation 3 is formed between an upper layer portion of the first substrate section 7 and an upper layer portion of the second substrate section 8. The first gate insulating film 13, the second semiconductor layer 10B and the first semiconductor layer 10A are layered on the top surface of the first substrate section 7, and these are covered with an insulating film 41 and an insulating layer 42. In addition, a gate oxide film 43 is formed on the top surface of the second substrate section 8, the semiconductor layer 20B and the first semiconductor layer 20A are layered on the gate oxide film 43, and these are covered with the insulating film 41 and the insulating layer 42.

As an example, a film thickness of the first gate insulating film 13 is about 10 nm or less, and a film thickness of the gate oxide film 43 is about 40 nm.

In the following description of the manufacturing method based on FIG. 2 to FIG. 5, disclosure and description of these regions will be omitted, and the structures of the first transistor 5 and the second transistor 6 formed on the substrate on the side of the upper portion will be mainly described.

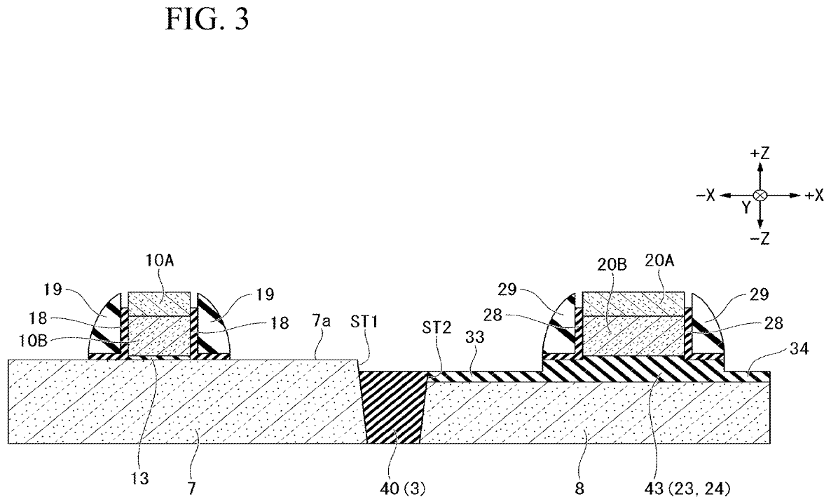

From the state shown in FIG. 2, for the region where the first transistor should be formed by performing etching, as shown in FIG. 3, the insulating sidewall 29 is formed at both sides of the second semiconductor layer 10B and the first semiconductor layer 10A. Simultaneously, for the region where the second transistor should be formed, the insulating sidewall 29 is formed on both sides of the second semiconductor layer 20B and the first semiconductor layer 20A. The insulating layer 42 and the insulating film 41 formed at both sides of the second semiconductor layer 10B in the X direction are partially removed through the above-mentioned etching, and thus, the insulating sidewall 19 is formed. Simultaneously, the insulating film 18 remains partially between the second semiconductor layer 10B, the first semiconductor layer 10A and the insulating sidewall 19.

The insulating layer 42 and the insulating film 41 formed at both sides of the second semiconductor layer 20B in the X direction are partially removed through the above-mentioned etching, and the insulating sidewall 29 is formed. Simultaneously, a structure in which the insulating film 28b remains partially is formed between the second semiconductor layer 20B, the first semiconductor layer 20A and the insulating sidewall 29. The gate oxide film 43 foamed on the top surface 8a of the second substrate section 8 is partially removed through the above-mentioned etching. Regions in the gate oxide film 43 on both sides of the second semiconductor layer 20B in the X direction, which are not covered with the insulating sidewall 29, are etched through the above-mentioned etching such that a film thickness is reduced.

In this case, etching is performed on the gate oxide film 43 to remain the side of the bottom portion in the film thickness direction with a uniform thickness without removing the gate oxide film 43 in the film thickness direction as a whole. The first portion 24, the second portion 33 and the third portion 34 can be formed on the gate oxide film 43 in the second substrate section 8 through etching. When etching is performed on the gate oxide film 43 to remain the side of the bottom portion in the film thickness direction with a uniform thickness, as shown in FIG. 3, the upper surface of the insulating portion 40 can be processed to be substantially flush with the upper surface of the second portion 33, and the isolation 3 can be formed from the insulating portion 40.

When a bottom portion of the gate oxide film 43 in the second substrate section 8 remains, as an example, the gate oxide film 43 can be etched to remain a film thickness of about 10 nm.

The insulating layer 42 and the insulating film 41 Rained at both sides of the second semiconductor layer 10B in the X direction can be removed on the side of the upper surface of the first substrate section 7, and the insulating sidewalls 19 and 19 can be formed at both sides of the second semiconductor layer 10B. In addition, the insulating layer 42 and the insulating film 41 formed on the top surface of the first substrate section 7 are removed as a whole on both sides of the insulating sidewalls 19 and 19 in the X direction.

In the state shown in FIG. 3, the step difference ST I is formed on the top surface 7a of the first substrate section 7 and the upper surface of the isolation 3, the step difference ST2 is formed between the top surface of the isolation 3 and the top surface of the second substrate section 8.

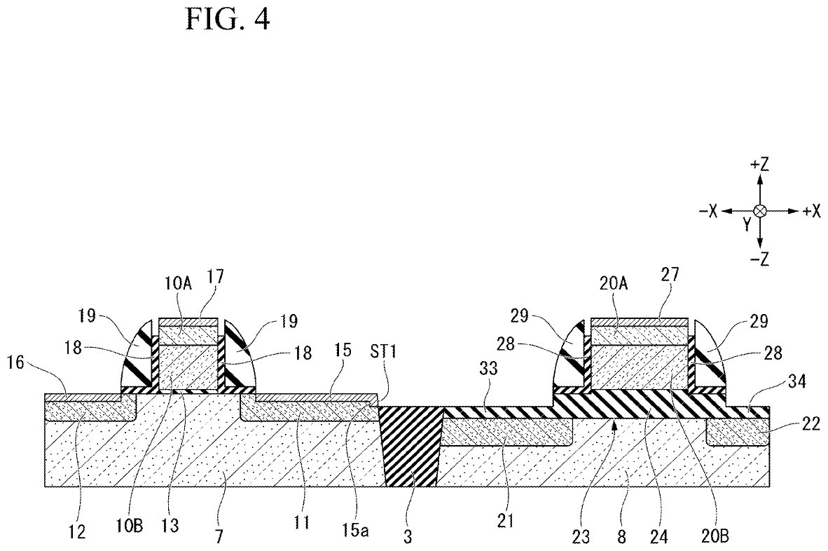

Next, metallic elements such as nickel, platinum, or the like, are supplied to the top surface of the first substrate section 7 and the top surfaces of the first semiconductor layers 10A and 20A, and heat treatment is performed. Accordingly, as shown in FIG. 4, the first-diffusion-layer-side silicide layer 15, the second-diffusion-layer-side silicide layer 16, the first gate silicide layer 17, and the second gate silicide layer 27 can be formed. While a metal layer is formed in a region to which the metallic elements are supplied in advance, when the metal layer is removed through etching, the structure shown in FIG. 4 is obtained.

The first gate silicide layer 17 can be formed on the top surface of the first semiconductor layer 10A in a first transistor forming region. The second gate silicide layer 27 can be formed on the top surface of the first semiconductor layer 20A in a second transistor forming region.

That is, the first gate silicide layer 17 and the second gate silicide layer 27 are simultaneously formed. In addition, the first-diffusion-layer-side silicide layer 15 and the second-diffusion-layer-side silicide layer 16 can be formed on the top surface of the first substrate section 7 on the sides of the pair of insulating sidewalls 19.

As shown in the cross section of the semiconductor device 1 of FIG. 1, since the first-diffusion-layer-side silicide layer 15 and the second-diffusion-layer-side silicide layer 16 can be formed by supplying metallic elements such as nickel, platinum, or the like, to the first source region 11 and the first drain region 12 and diffusing the metallic elements through heat treatment, the silicide layers 15 and 16 can be formed as self-alignment.

While the first-diffusion-layer-side silicide layer 15 is formed to a predetermined depth from the top surface 7a of the first substrate section 7, the step difference ST1 is formed on the boundary portion between the top surface 7a of the first substrate section 7 and the upper surface of the isolation 3. For this reason, the extension portion 15a is formed along an appearance of the step difference ST1. The thickness of the first-diffusion-layer-side silicide layer 15 in the Z direction of the extension portion 15a is formed to be larger than the thickness of the first-diffusion-layer-side silicide layer 15 in the portion except the extension portion 15a.

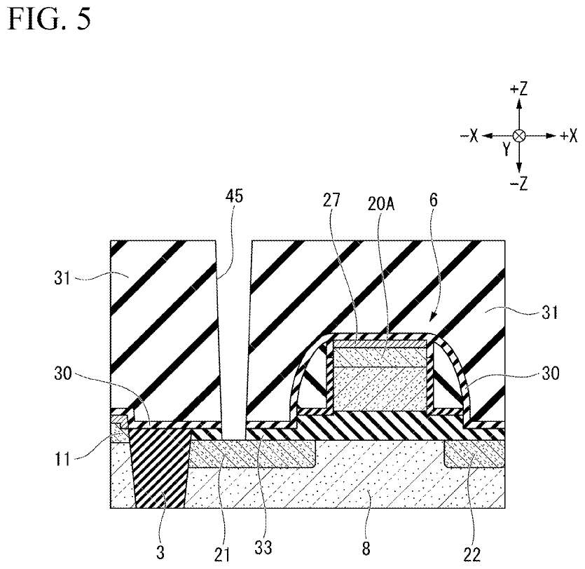

As shown in FIG. 5, the protective film 30 is formed. Next, the insulating layer 31 is formed on the protective film 30. After that, for example, a contact hole 45 is formed at a position where the insulating layer 31 is required as shown in FIG. 5.

The contact hole 45 exemplified in FIG. 5 is formed to pass through the insulating layer 31, the protective film 30 and the second portion 33 of the gate insulating film 23 to reach the top surface 8a of the second substrate section 8. When the contact hole 45 is filled with a conductive material or the like, the third contact electrode 37 shown in FIG. 1 can be obtained.

Further, while not shown, the first contact electrode 35, the second contact electrode 36, and the fourth contact electrode 38 can be formed by a method of forming a contact hole and filling the contact hole with a conductive material in the same manner as described above.

The first contact electrode 35 is formed to pass through the insulating layer 31 and the protective film 30 and reach the first gate silicide layer 17. The second contact electrode 36 is formed to pass through the insulating layer 31 and the protective film 30 and reach the first-diffusion-layer-side silicide layer 15. The fourth contact electrode 38 is formed to pass through the insulating layer 31 and the protective film 30 and reach the second gate silicide layer 27.

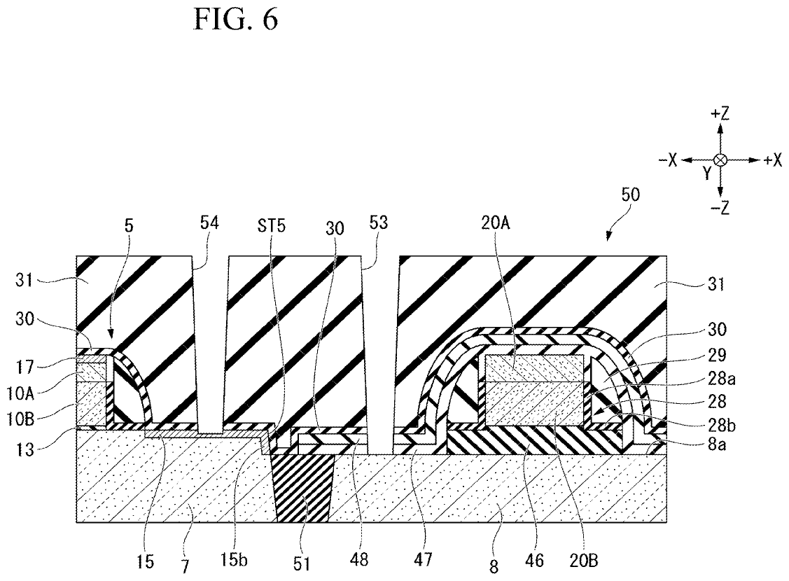

The semiconductor device 1 of the structure shown in FIG. 1 can be manufactured by employing the manufacturing method described with reference to FIG. 2 to FIG. 5. According to the semiconductor device 1 shown in FIG. 1, it is possible to provide a semiconductor device capable of obtaining various effects as described below. Further, before describing the effects of the semiconductor device 1, a semiconductor device of a comparative example structure shown in FIG. 6 will be described.

While semiconductor device 50 of a comparative example showing in FIG. 6 has a structure similar to that of the semiconductor device 1 shown in FIG. 1, a structure around the second transistor is mainly different from a structure around the insulating portion.

In the semiconductor device 50 shown in FIG. 6, both ends of a second gate insulating film 46 in the X direction are disposed below the bottom portion 28b of the insulating film 28. Accordingly, the second portion 33 and the third portion 34 disposed in the semiconductor device 1 shown in FIG. I are not formed in the semiconductor device 50. Instead of this, a first block film 47 and a second block film 48 are disposed at positions corresponding to the second portion 33 and the third portion 34.

In addition, in the semiconductor device 50 shown in FIG. 6, a fifth step difference ST5 is formed between the top surface 7a of the first substrate section 7 and a top surface of an isolation 51. An extension portion 15b of the first-diffusion-layer-side silicide layer 15 is formed along the fifth step difference ST5. A thickness (depth) of the extension portion 15b in the Z direction is greater than a thickness (depth) of the extension portion 15a of the semiconductor device 1 in the Z direction shown in FIG. 1. The reason for this is that the second portion 33 of the second gate insulating film 23 is not formed on the top surface 8a of the second substrate section 8, and this is due to the fact that an upper surface of an insulating portion 51 is flush with the top surface 8a of the second substrate section 8. For this reason, the fifth step difference ST5 is greater than the first step difference ST1 shown in FIG. 1.

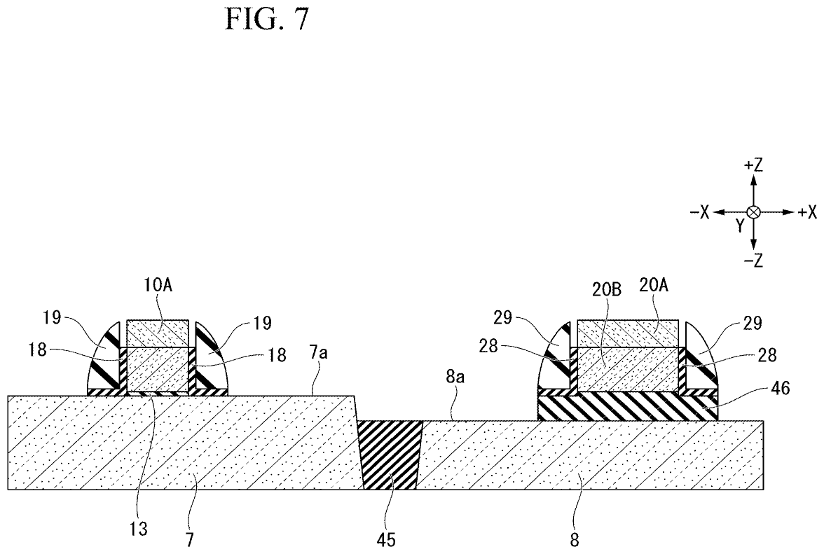

FIG. 7 is a cross-sectional view related to a process of manufacturing the semiconductor device 50, which corresponds to a state shown in FIG. 3 when the semiconductor device 1 is manufactured. As shown in FIG. 7, when the semiconductor device 50 is manufactured, in the region in which the second transistor 6 is formed, the gate oxide film located on the top surface 8a of the second substrate section 8 is removed as a whole on outer sides of the pair of insulating sidewalls 29. Accordingly, both end portions of the second gate insulating film 46 in the X direction after the gate oxide film is processed are present at positions below the pair of insulating sidewalls 29. Accordingly, the second portion 33 and the third portion 34 of the second gate insulating film 23 disposed on the semiconductor device 1 shown in FIG. 1 is not formed in the semiconductor device 50.

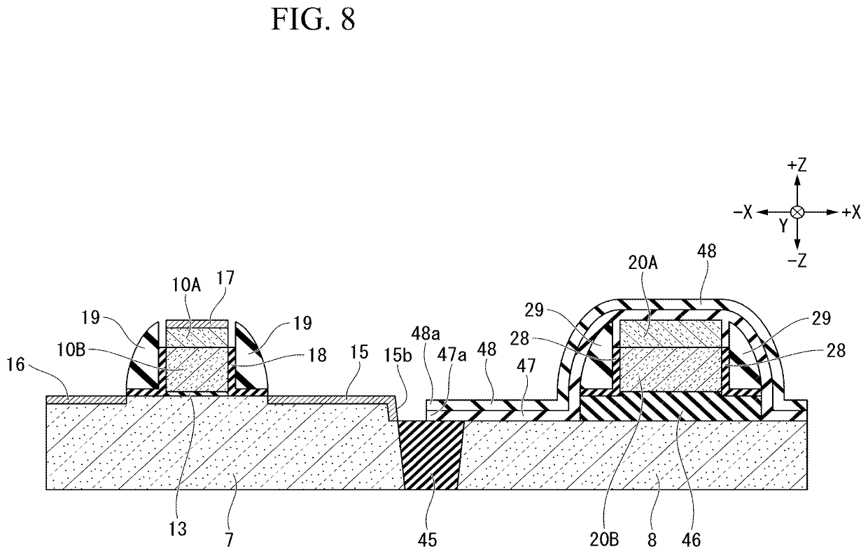

From the state shown in FIG. 7, as shown in FIG. 8, in forming the first-diffusion-layer-side silicide layer 15 and the second-diffusion-layer-side silicide layer 16 on the top surface 7a of the first substrate section 7, in order to protect the top surface 8a of the second substrate section 8, there is a need to laminate the first block film 47 and the second block film 48. The first block film 47 is formed of, for example, a silicon oxide film. The second block film 48 is formed of, for example, a silicon nitride film. The first block film 47 and the second block film 48 formed herein should be formed to cover the top surface 8a of the second substrate section 8 to the vicinity of the central portion of the isolation 51 in the X direction in order to reliably protect the top surface 8a.

When the protective film 30 and the insulating layer 31 are formed on the structure shown in FIG. 8, a structure corresponding to the semiconductor device 50 of the comparative example shown in FIG. 6 is shown. In the semiconductor device 50 of the comparative example shown in FIG. 6, an extension portion 15b of the first-diffusion-layer-side silicide layer 15 is formed long (deep) in the Z direction due to a large size of the fifth step difference STS. When the extension portion 15b is formed long (deep) in the configuration of the semiconductor device 50, there is a concern that the leak current will increase as a transistor.

On the other hand, since the top surface of the isolation 3 is disposed at a position higher than the top surface 8a of the second substrate section 8 by forming the second portion 33 on the structure of FIG. 1, a length (depth) of the extension portion 15a of the first-diffusion-layer-side silicide layer 15 in the Z direction can be shortened (shallow). For this reason, the semiconductor device 1 shown in FIG. 1 can minimize an increase in the leak current in comparison with the semiconductor device 50 shown in FIG. 6.

The reason for reducing the length of the extension portion 15a in the Z direction is that supply of a metal such as nickel, platinum, or the like, to a position deeper than the upper surface of the isolation 3 in the portion of the step difference ST can be minimized when the metal is supplied to the first source region 11.

In the structure in which the first block film 47 and the second block film 48 are disposed on the isolation 51 shown in FIG. 6, in order for the block film to function sufficiently as a block film during silicide formation, it is necessary to secure a sufficiently large width of the isolation 51 in the X direction.

For example, an end portion 47a of the first block film 47 and an end portion 48a of the second block film 48 are disposed on the isolation 51. In order to reliably form the end portions 47a and 48a on the isolation 51 in consideration of etching unevenness, it is necessary to secure a sufficiently large width of the isolation 51 in the X direction.

However, when the width of the isolation 51 in the X direction is increased, it leads to reduction of the element region where the first transistor 5 and the second transistor 6 are disposed, which may make it difficult to increase the density of the element disposition.

In the semiconductor device 1 shown in FIG. 1, a part of the gate insulating film that constitutes the gate insulating film 23 extends to the side surfaces of the isolation 3 as the second portion 33. The second portion 33 can also serve as a block film when the silicide layers 15 and 16 are formed. Accordingly, in the semiconductor device 1, there is no need to provide a special block film, and as a result, there is also no need to enlarge the width of the isolation 3 in the X direction. In addition, the second portion 33 of the gate insulating film 23 can be utilized as the block film regardless of the width of the isolations 3 in the X direction. Accordingly, in the semiconductor device 1, the width of the isolation 3 in the X direction can be reduced in comparison with the semiconductor device 50, Reduction in width of the isolations 3 in the X direction contributes to reduction in size of the semiconductor device 1 and contributes to improvement of the degree of integration as the semiconductor device 1.

In addition, in the configuration shown in FIG. 1, since the fourth contact electrode 38 is connected onto the second gate electrode 20 of the second transistor 6 via the second gate silicide layer 27, even when the gate electrode is long, a margin improvement effect can be obtained for the fall of potential or delay.

In the semiconductor device 1 shown in FIG. 1, introduction of the silicide layers 15 and 16 in the first transistor 5 is performed, and introduction of the silicide layer is not performed in order to secure a pressure proof in the second transistor 6 while achieving reduction in parasitic resistance. In the embodiment, as described above, the semiconductor device 1 in which the silicide layer is distributed according to the transistor can be manufactured and disposed without adding a special process.

In addition, the first gate silicide layer 17 is disposed on the first gate electrode 10 of the first transistor 5, and the second gate silicide layer 27 is disposed on the second gate electrode 20 of the second transistor 6.

For this reason, both of the contact portion with respect to the first gate electrode 10 and the contact portion with respect to the second gate electrode 20 can be connected in a state in which a parasitic resistance is low.

Next, the case in which the third contact electrode 37 is formed in the semiconductor device 1 shown in FIG. 1 is compared with a case in which contact holes 53 and 54 for forming contact electrodes with respect to a diffusion region of the second substrate section 8 in the semiconductor device 50 shown in FIG. 6 are formed, which will be described below.

In the semiconductor device I shown in FIG. 1, when a contact hole that reaches the second source region 21 is formed, contact holes passing through the insulating layer 31, the protective film 30 and the second portion 33 of the second gate insulating film 23 are formed. On the other hand, in the semiconductor device 50 shown in FIG. 6, it is necessary to form the contact hole 53 passing through the first block film 47 and the second block film 48 in addition to the insulating layer 31 and the protective film 30.

Next, in the semiconductor device 50 shown in FIG. 6, the case in which the contact hole 54 that reaches first diffusion layer-side silicide region 15 of the first substrate section 7 are formed in addition to the contact hole 53 will be considered below.

When the contact hole 53 is formed, the contact hole 53 is formed to pass through the second block film 48 and the first block film 47 below the protective film 30. Simultaneously, in forming the contact hole 54, an etching condition is that only one layer, the first-diffusion-layer-side silicide layer 15, is present below the protective film 30. For this reason, when the etching condition is set to pass through the first block film 47 and the second block film 48, over etching of the contact hole 54 on the side of the bottom portion may occur. When the contact hole 54 is formed to penetrate the first-diffusion-layer-side silicide layer 15, since the contact electrode is generated through the first-diffusion-layer-side silicide layer 15, the contact electrode can cause a short circuit.

On the other hand, in the semiconductor device 1 shown in FIG. 1, there is a structure in which the second portion 33 is present under the protective film 30 by one layer. In addition, there is a structure in which only one layer, the first-diffusion-layer-side suicide layer 15, is present below the protective film 30 on the side of the lower end of the second contact electrode 36 in the semiconductor device 1 of FIG. 1.

For this reason, a processing margin when the contact hole for the second contact electrode 36 and the contact hole for the third contact electrode 37 are formed can be increased more than in the structure shown in FIG. 6. For example, the over etching amount generated in the contact hole 54 when the semiconductor device 50 shown in FIG. 6 is manufactured can be reduced when the semiconductor device 1 shown in FIG. 1 is manufactured.

Accordingly, in the semiconductor device 1 shown in FIG. 1, compared with the semiconductor device 50 shown in FIG. 6, it is possible to obtain the effect that the contact electrode 36 can be surely formed with good contact property with respect to the first-diffusion-layer-side silicide layer 15. Further, a structure in which the bottom portion of the contact hole reaches the upper surface of the first substrate section 7 through the above-mentioned over etching and the contact electrode is formed at a position where the upper surface of the first substrate section 7 is damaged is considered.

In the case of the structure, a so-called high flyer phenomenon in which a contact of the contact electrode to the side of the semiconductor substrate becomes unstable and a jump value occurs at the time of conduction may occur. Incidentally, when the semiconductor device 1 of FIG. 1 is employed, the high flyer phenomenon can be minimized.

In addition, like the structure shown in FIG. 6, when there is the structure in which the first block film 47 and the second block film 48 are disposed, there is a need to add a plurality of processes including a film forming process of two films, an ion etching process, and a photolithography process such as an etching process by etchant or the like with respect to the structure shown in FIG. 1.

In this point, according to the structure of FIG. 1, it is possible to provide the semiconductor device 1 including the first transistor 5 capable of high-speed operation and the second transistor 6 ensuring pressure proof without increasing a special process.

Incidentally, the semiconductor device 1 shown in FIG. 1 is applied to a semiconductor storage device. In this case, for example, the second transistor 6 can be used as a transistor configured to apply a relatively high voltage for changing a storage state of the memory cell to the memory cell, and the first transistor 5 can be used as a transistor for applying a relatively low voltage for the case in which information is read from the memory cell, or the like. When the first transistor 5 and the second transistor 6 are applied to the current semiconductor storage device, it is considered difficult to form a silicide layer in the diffusion region because the second transistor 6 secures a withstand voltage.

According to the structure shown in FIG. 1, the region in which the silicide layer is formed in a self-alignment manner is formed only in the first transistor 5, and in the diffusion region of the second transistor 6, the structure in which the silicide layer is not formed can be distributed. According to the structure shown in FIG. 1, the silicide layer can be created using the second portion 33 without the need for the block film. Accordingly, it is possible to manufacture the semiconductor device 1 with excellent electrical properties including the first transistor 5 and the second transistor 6 that are desired, without adding a special process.

Further, the semiconductor device 1 shown in FIG. 1 can be generally and widely applied to a device configured to apply different voltages and control electronic instruments using the first transistor 5 and the second transistor 6. For this reason, the semiconductor device 1 can be widely applied to a control device or a control circuit other than the semiconductor storage device using different control voltages.

Hereinabove, while the embodiments and variants have been described, the embodiments are not limited to the above-mentioned examples. For example, the above-mentioned two or more embodiments and variants may be combined and realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a first transistor including:
a first diffusion region in the substrate,
a second diffusion region in the substrate,
a first gate insulating film over the substrate,
a first gate electrode over the first gate insulating film;
a first silicide layer in contact with the first diffusion region;
a second silicide layer in contact with the second diffusion region; and
a first gate silicide layer in contact with the first gate electrode; and
a second transistor including:
a third diffusion region in the substrate;
a fourth diffusion region in the substrate;
a second gate insulating film over the substrate;
a second gate electrode over the second gate insulating film; and
a second gate silicide layer in contact with the second gate electrode,
wherein the second gate insulating film is thicker than the first gate insulating film, and at least a part of the third diffusion region and at least a part of the fourth diffusion region are covered by the second gate insulating film.

2. The semiconductor device according to claim 1, wherein the substrate has a first substrate section over which the first transistor is disposed, and the substrate has a second substrate section over which the second transistor is disposed, the substrate has a step difference between the first substrate section and the second substrate section, the second substrate section is thinner than the first substrate section.

3. The semiconductor device according to claim 1, wherein the second gate insulating film includes a first portion positioned between the substrate and the second gate electrode, a second portion on the third diffusion region, and a third portion on the fourth diffusion region, and
wherein the second portion and the third portion are smaller in thickness in a thickness direction of the substrate than the first portion.

4. The semiconductor device according to claim 1, wherein the second portion is greater in thickness in the thickness direction of the substrate than the first gate insulating film.

5. The semiconductor device according to claim 1, wherein the second portion is greater in thickness in the thickness direction of the substrate than the second gate silicide layer.

6. The semiconductor device according to claim 1,
wherein the substrate has a first substrate section over which the first transistor is disposed, and the substrate has a second substrate section over which the second transistor is disposed, the substrate has a step difference between the first substrate section and the second substrate section, the second substrate section is thinner than the first substrate section, and
wherein the second portion is positioned between the first portion and the step difference.

7. The semiconductor device according to claim 1,
wherein the substrate has an isolation between the first substrate section and the second substrate section the isolation isolates the first diffusion region and the third diffusion region, and
wherein the second portion of the second gate insulating film is in contact with the isolation.

8. The semiconductor device according to claim 1, wherein the first gate silicide layer and the second gate silicide layer are positioned at the same level in the thickness direction of the substrate.

9. The semiconductor device according to claim 1, further comprising:
a protective film that covers the first transistor and the second transistor, the protective film is in contact with the first silicide layer, the second silicide layer, the second portion of the gate insulating film, and the third portion of the gate insulating film.

10. The semiconductor device according to claim 1, wherein the protective film is in contact with the first gate silicide layer and the second gate silicide layer.

11. The semiconductor device according to claim 1, further comprising:
a first contact electrode connected to the first gate silicide layer;
a second contact electrode connected to the first silicide layer;
a third contact electrode connected to the third diffusion region; and
a fourth contact electrode connected to the second gate silicide layer.

12. A method of manufacturing a semiconductor device, the method including:
selectively supplying metal elements into a substrate and performing a heat treatment to form a first diffusion region, a second diffusion region, a third diffusion region and a fourth diffusion region in the substrate;
forming a first gate insulating film and a second gate insulating film over the substrate;
forming a first gate electrode and a second gate electrode over the first gate insulating film and the second gate insulating film, respectively; and
forming a first silicide layer in contact with the first diffusion region and a second silicide layer in contact with the second diffusion region, while the second gate insulating film covering the third diffusion region and the fourth diffusion region without forming any silicide layer in the third diffusion region and the fourth diffusion region,
wherein the second gate insulating film is thicker than the first gate insulating film, and the second gate insulating film covers at least a part of the third diffusion region and at least a part of the fourth diffusion region.
